(19) United States
(12) Patent Application Publication
(10) Pub. No.: US 2014/0069622 A1
(43) Pub. Date: Mar. 13, 2014

(54) HEAT DISSIPATION COMPOSITE AND THE USE THEREOF

(71) Applicants: Ko-Chun CHEN, Kaohsiung (TW); Chiu-Lang Lin, Kaohsiung County (TW)

(72) Inventors: Ko-Chun CHEN, Kaohsiung (TW); Chiu-Lang Lin, Kaohsiung County (TW)

(21) Appl. No.: 13/938,138

(22) Filed: Jul. 9, 2013

Related U.S. Application Data
(60) Provisional application No. 61/699,140, filed on Sep. 10, 2012.

(51) Int. Cl. H05K 7/20; F28F 3/00

(52) U.S. Cl. CPC H05K 7/2039; F28F 3/00
USPC 165/185; 428/221; 428/354

(57) ABSTRACT

A multi-layer heat dissipation composite for reducing the external surface temperature of an electronic device is disclosed. The heat dissipation composite comprises a reflective component and a component with anisotropic property. The heat dissipation composite further comprises an adhesive. Some embodiments also provide methods for reducing the external surface temperature of an electronic device.

### CROSS-REFERENCE TO RELATED APPLICATIONS

This application claims priority to U.S. Provisional Patent Application No. 61/669,140, filed Jul. 9, 2012, the contents of which is incorporated herein by reference in its entirety.

### BACKGROUND OF THE INVENTION

Excessive heat generation caused by the operation of small handheld personal electronic devices, such as cell phones, e-readers and other such devices, is an increasingly challenging problem as the size of such devices continue to shrink, while their performance, and thus heat output, continues to grow. The heat generated by internal electronic components can lead to high external surface temperatures on the outside surface of such devices and result in user discomfort, such as discomfort in a person's lap or palm. Such discomfort can lead to customer complaints, warranty claims and a diminished reputation in the market place. Thus, the thermal management of the sealed electronic enclosures of such devices presents an increasing challenge to the designers and engineers involved in the development of such products.

### BRIEF SUMMARY OF THE INVENTION

An exemplary embodiment provides a better heat dissipation device for electronic enclosures to aid in reducing the overheating of internal components of such devices and therefore their concomitant external surface temperature.

Some embodiments are directed to a device comprising a heat dissipation composite that uses two or more heat dissipation mechanisms to enhance heat dissipation and reduce the external surface temperature of an electronic device. The composite of some embodiments can have applications in various electronic devices such as computers, cellular phones, LCD or LED display panels, LED lights used in conjunction with printed circuit boards (PCBs), LCD backlight units (BLU) and the like.

In one embodiment, the device comprise a heat dissipation composite, comprising a reflective film configured to reflect heat or thermal energy and an anisotropic component, wherein the reflective film forms an outer major surface boundary of the composite. In another embodiment, the device comprises a heat dissipation composite, comprising a reflective film configured to reflect thermal energy; a metal layer; and a graphite sheet, wherein the metal layer is interposed between the reflective film and the graphite sheet.

the heat dissipation composite is a multi-layer structure, comprising a heat reflective film with a reflectivity of at least 70%; an electroplated metal layer selected from copper, nickel, chromium, gold, silver, tin, platinum, or combinations thereof; a flexible exfoliated graphite sheet; and one or more adhesives, wherein the electroplated metal layer is interposed between the adhesive and the graphite sheet, the adhesive is interposed between the reflective film and the electroplated metal layer.

In another embodiment, the device comprising a means for managing heat energy, comprising means for reflecting heat energy; and means for dissipating heat having an anisotropic property.

Embodiments are also directed to methods of dissipating heat and reducing the external surface temperature of an electronic device using the heat dissipation composite. The method includes the following steps:
(a) placing a heat dissipation composite in heat transfer communication (i.e., in direct physical contact or indirect contact, wherein there is a gap or an interposing layer) with the heat source;
(b) transferring heat from the heat source to the heat dissipating composite,
(c) reflecting a portion of the heat transferred from the heat source into the ambient air without passing through the heat dissipation composite; and
(d) dissipating a portion of the heat transferred from the heat source through the planar direction (i.e. X-Y plane) of the heat dissipation composite.

### BRIEF DESCRIPTION OF THE DRAWINGS

Other utilities of some embodiments will become apparent in the following detailed description of the embodiments, with reference to the accompanying drawings, in which:

FIG. 1 illustrates schematically a cross sectional view of the device's casing and one embodiment of the heat dissipation composite 1. The heat dissipation composite 1 comprises a reflective film 2, a metal layer 3 and a graphite sheet 4.

FIG. 2 illustrates schematically a cross sectional view of the device's casing and another embodiment of the heat dissipation composite 1. The heat dissipation composite 1 comprises the following layers: a reflective film 2, an adhesive 6, a metal layer 3 and a graphite sheet 4.

FIG. 3 illustrates schematically a cross sectional view of the device's casing and another embodiment of the heat dissipation composite 1. The heat dissipation composite comprises the following layers: a reflective film 2, a metal layer 3, a graphite sheet 4 and an adhesive 6.

FIG. 4 illustrates schematically a cross sectional view of the device's casing and another embodiment of the heat dissipation composite 1. The heat dissipation composite 1 comprises the following layers: a reflective film 2, an adhesive 6, a metal layer 3, an adhesive 6 and a graphite sheet 4.

FIG. 5 illustrates schematically a cross sectional view of the device's casing and another embodiment of the heat dissipation composite 1. The heat dissipation composite 1 comprises the following layers: a reflective film 2, a metal layer 3 and an insulating film 5.

FIG. 6 illustrates schematically a cross sectional view of the device's casing and another embodiment of the heat dissipation composite 1. The heat dissipation composite 1 comprises the following layers: a reflective film 2, an adhesive 6, a metal layer 3 and an insulating film 5.

FIG. 7 illustrates schematically a cross sectional view of the device's casing and another embodiment of the heat dissipation composite 1. The heat dissipation composite 1 comprises the following layers: a reflective film 2, a metal layer 3, an insulating film 5 and an adhesive 6.

FIG. 8 illustrates schematically a cross sectional view of the device's casing and another embodiment of the heat dissipation composite 1. The heat dissipation composite 1 comprises the following layers: a reflective film 2, an adhesive 6, a metal layer 3, an insulating film 5 and an adhesive 6.

FIG. 9 illustrates schematically the heat dissipation pathway of the heat dissipation composite 1 in FIG. 1.

FIG. 10 illustrates schematically the heat dissipation pathway of the heat dissipation composite 1 in FIG. 5.

FIG. 11 illustrates schematically the heat dissipation device in a computer laptop in the working example.

### DETAILED DESCRIPTION OF THE INVENTION

### Definition

As employed above and throughout the disclosure, the following terms, unless otherwise indicated, shall be understood to have the following meanings.

As used herein, the singular forms “a,” “an,” and “the” include the plural reference unless the context clearly indicates otherwise.

As used herein, the term “about,” when referring to a measurable value such as a thickness, and the like, is meant to encompass variations of ±10%, ±5%, ±1%, and/or ±0.1% from the specified value, as such variations are appropriate to the thickness of the reflective film, unless otherwise specified. As used herein, the term “about,” when referring to a range, is meant to encompass variations of ±10% within the difference of the range, ±5%, ±1%, and/or ±0.1% from the specified value.

### The Heat Dissipation Composite

An exemplary heat dissipation composite comprises an anisotropic component that has a higher thermal conductivity in a planar direction (e.g., in the x-y direction as illustrated, for example, in FIG. 1) than that in the through direction (e.g., in the z direction as illustrated, for example, in FIG. 1) and a reflective component that reflects heat to the surrounding atmosphere. The reflective film has a reflectivity of at least 70% as measured by CIR l*a*b* using D65 light source (6500K). As a result, the heat dissipation composite of at least some embodiments is more efficient in dissipating heat than a graphite sheet or a reflective film alone. In an exemplary embodiment, the reflective component has a reflectivity of at least about 75%, 80%, 85%, 90%, 95% and/or greater.

In an exemplary embodiment, the reflective component reflects about 50%, 55%, 60%, 65%, 70%, 75%, 80%, 85%, 90%, 95% or more of the incident radiation.

In one group of embodiments, the anisotropic component of the heat dissipation composite is graphite. In another group of embodiment, the anisotropic component of the heat dissipation composite comprises a metal layer and an insulating film. In yet another group of embodiment, the anisotropic component of the heat dissipation composite comprises a metal layer and an insulating film, and is devoid of graphite.

In one group of embodiments, the heat dissipation composite comprises a reflective film configured to reflect heat energy and a graphite sheet, substantially free of thermoplastic polyester foamed material. In another embodiment, the heat dissipation composite consists essentially of reflective film, a metal layer and a graphite sheet.

In an exemplary embodiment, the heat dissipation composite further comprises a metal layer, as illustrated in FIGS. 1 to 4, wherein the heat dissipation composite 1 comprises a reflective film 2, a metal layer 3 and a graphite sheet 4, placed adjacent to one another.

In one embodiment, the metal layer 3 is electroplated onto the graphite sheet 4 according to the method disclosed in U.S. Pub. No. 2010/0243230, which teachings pertaining to electroplating are incorporated herein by reference in their entirety. In an exemplary embodiment, the graphite sheet 4 is cleaned with an acid solution or plasma solution at atmospheric pressure, followed by electroplating the metal on the graphite sheet 4. In another embodiment, the metal layer 3 is adhered to the graphite sheet 4 using a double-sided adhesive or other means. In an exemplary embodiment, the metal layer is in direct physical contact with one of the major surfaces of the graphite sheet layer and does not cover any of the edges of the graphite sheet. The metal layer 3 prevents the flaking of and provides stiffness to the graphite sheet 4.

In another group of embodiments, the heat dissipation composite comprises a reflective film 2, a metal layer 3 and an insulating film 5, placed adjacent to one another. (See FIGS. 5 to 8.) By forming the heat dissipation composite in this manner, the anisotropic thermal conductivity is achieved by the juxtaposition of high (metal) and low (insulating film) thermal conductivity materials.

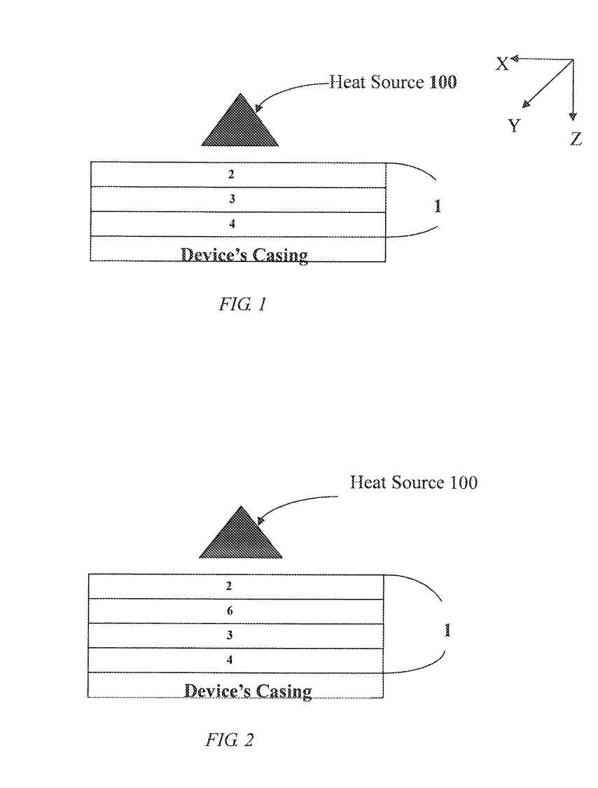

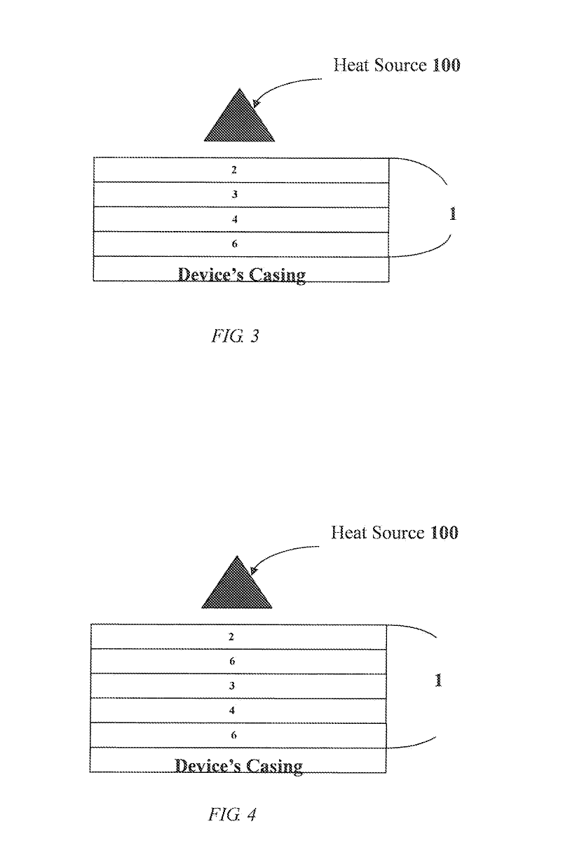

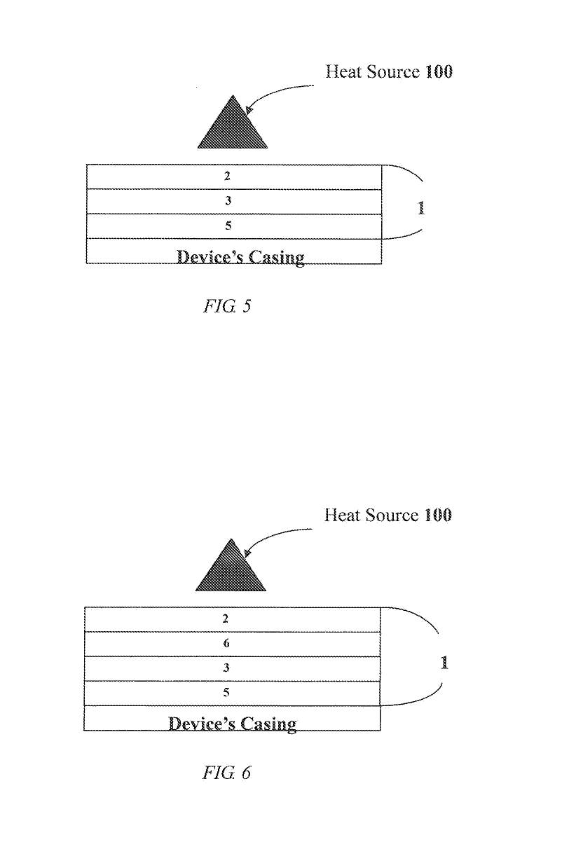

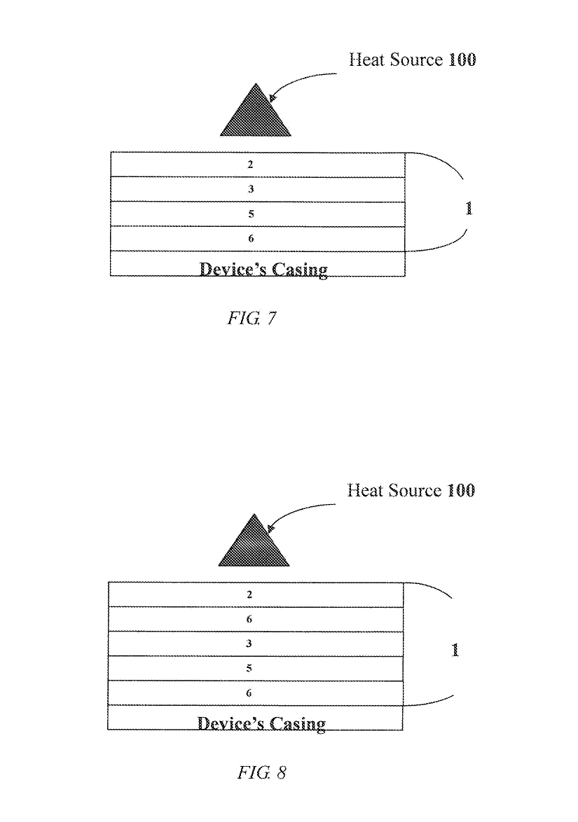

In another embodiment, the heat dissipation composite 1 further comprises an adhesive 6 or other means for adhering the reflective film to the metal layer (e.g., as in FIG. 2, FIG. 4, FIG. 6 and FIG. 8). In another embodiment, the reflective film is in direct physical contact with the metal layer, without any interposing adhesive (e.g., as in FIG. 1, FIG. 3, FIG. 5 and FIG. 7).

In an exemplary embodiment, the insulating film is in direct physical contact with one of the major surfaces of the metal layer and does not cover any of the edges of the metal layer.

The heat dissipation composite 1 is adhered to an electronic device's casing using an adhesive 6 (e.g., as in FIG. 3, FIG. 4, FIG. 7 and FIG. 8) or is in direct physical contact with an electronic device's casing (e.g., as in FIG. 1, FIG. 2, FIG. 5 and FIG. 6).

In one embodiment, the heat dissipation composite 1 reduces the external surface temperature of an electronic device by about 7.5° C. to about 20° C. relative to no heat dissipation composite. In another embodiment, the heat dissipation composite 1 reduces the external surface temperature of an electronic device by about 8, 9, 10, 11, 12, 13, 14, 15, 16, 17, 18 or 19° C. relative to no heat dissipation composite.

### Reflective Film

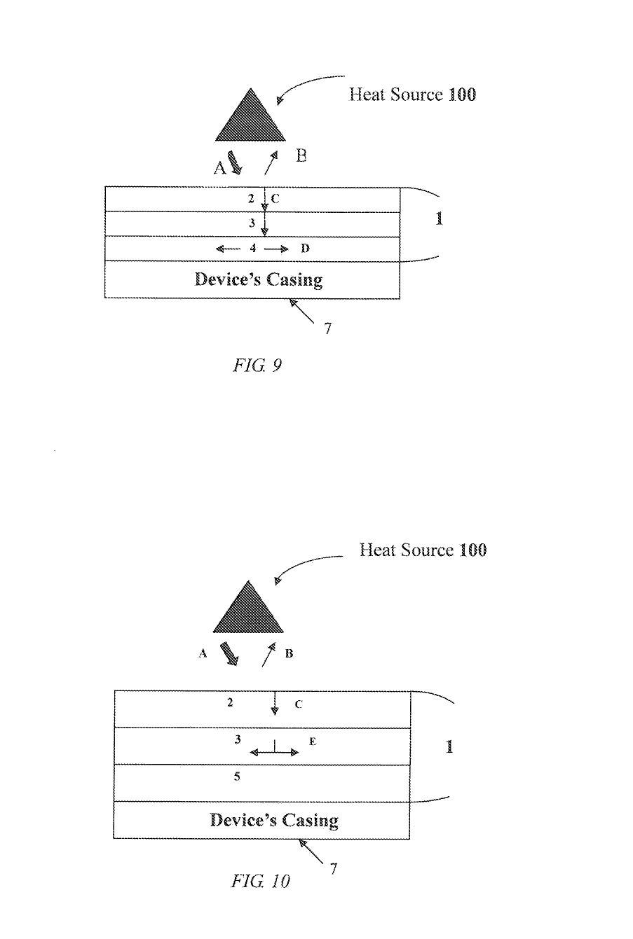

The reflective film used in some embodiments attenuates heat radiation. As illustrated in FIG. 9, the heat from the heat source 100 hits the reflective film 2 (Pathway A). The reflective film 2 reflects a portion of the heat from the heat source to the surrounding atmosphere (Pathway B). This reduces the amount of heat passing through the composite and therefore reduces the amount of heat reaching the device's casing.

In an exemplary embodiment, the performance characteristics detailed herein are related to heat radiation/heat energy that corresponds to the infrared part of the electromagnetic spectrum. In an exemplary embodiment, the performance characteristics detailed herein are related to heat radiation/heat energy that corresponds to radiation having a wavelength of more than about 750 nm and/or between about 750 nm to about 1 mm.

The reflective film comprises a base material with a reflective layer. A protection layer is optionally disposed on the reflective coating to avoid oxidation of the reflective coating.

The base material can be a glass, a plastic or a metal such as aluminum. A wide variety of reflective layers can be used as the reflective film. Examples of reflective coatings useful in at least some embodiments include, but are not limited to, indium, tin, gold, platinum, zinc, silver, copper, titanium, lead, an alloy of gold and beryllium, an alloy of gold and germanium, nickel, an alloy of lead and tin and an alloy of gold and zinc. In an exemplary embodiment, the reflective coating is made of silver. In another exemplary embodiment, the reflective coating is substantially free of optical fiber.

The protection layer can comprise an antioxidant such as metal oxides, silicon oxides, metal nitrides, silicon nitrides and other appropriate antioxidants.

The reflective film can have, in some embodiments, a reflectivity of at least 70% as measured by CIR l*a*b* using D65 light source (6500K) and/or a reflectivity as otherwise detailed herein and the thickness is about 0.05 mm to about 0.5 mm.

The reflective film faces the heat source directly, i.e., there is no interposing layer between the reflective film and the heat source.

### Graphite Sheet

The graphite sheet in the heat dissipation composite can be prepared from natural, synthetic or pyrolytic graphite particles. An example of natural graphite used in at least some embodiments includes, but is not limited to, flexible exfoliated graphite (made by treating natural graphite flakes with substances that intercalate into the crystal structure of the graphite). The thermal conductivity of the graphite sheet is anisotropic, i.e., high in the direction parallel to the major faces of the flexible graphite sheet (in-plane conductivity) and substantially less in the direction transverse to the major surfaces of the graphite sheet (through-plane conductivity). In an exemplary embodiment, anisotropic ratio of the graphite sheet, defined as the ratio of in-plane conductivity to through-plane conductivity, is between about 2 to about 800. The graphite sheet can be about 0.01 mm to about 0.5 mm.

### Metal Layer

The metal layer 3 in some embodiments is isotropic in nature, i.e., it has a higher thermal conductivity in a through direction (e.g., in the z direction as illustrated, for example, in FIG. 1) than that in planar the direction (e.g., in the x-y direction as illustrated, for example, in FIG. 1). The metal layer 3 is selected from the group consisting of copper, nickel, chromium, gold, silver, tin, platinum, and combinations thereof. In some embodiments, the metal layer 3 has a thickness of no less than about 1 μm.

In some embodiments, the metal layer 3 includes two metal films wherein a cooper film having a thickness ranging from 8 μm to 10 μm is formed on the graphite sheet 4, and a nickel film having a thickness ranging from 2 μm to 5 μm is formed on the copper film.

### Insulating Film

Suitable materials for the insulating film 5 include, but are not limited to, resin, polyester (e.g., polyethylene terephthalate or PET) and polyimide materials. An exemplary material is PET, with a thickness of about 0.001 mm to about 0.05 mm. The insulating film can be applied to the metal layer by various methods known in the field, such as by coating, using a hot laminating process, or by adhesion.

### Adhesive

An adhesive 6 is disposed between the reflective film 2 and the metal layer 3, and/or between the heat dissipation composite and the electronic device's casing or a heat sink. The adhesive is a double-sided adhesive tape, including a pressure sensitive adhesive coating and a release liner. The thickness of the adhesive is about 0.005 mm to about 0.05 mm. Examples of suitable adhesives useful in at least some embodiments include, but are not limited to, 3M 6T16 adhesive and 3M 6602 adhesive, both are commercially available from 3M, USA. In one exemplary embodiment, the refractive index is above about 1.30.

### The Method of Heat Dissipation

FIG. 9 illustrates the heat transfer pathway of the heat dissipation composite and an exemplary method of reducing the external surface 7 temperature of an electronic device. In this method, the heat dissipation composite 1 is placed in direct physical contact or indirect contact with the heat source of an electronic device 100; heat from the heat source 100 is then transferred to the heat dissipating composite (pathway A), wherein a portion of the heat is reflected into the ambient air (pathway B); and the remaining heat travels through the thickness of the reflective layer 2 and the metal layer 3 (pathway C), which then spreads across the planar direction of the anisotropic graphite sheet 4 (pathways D).

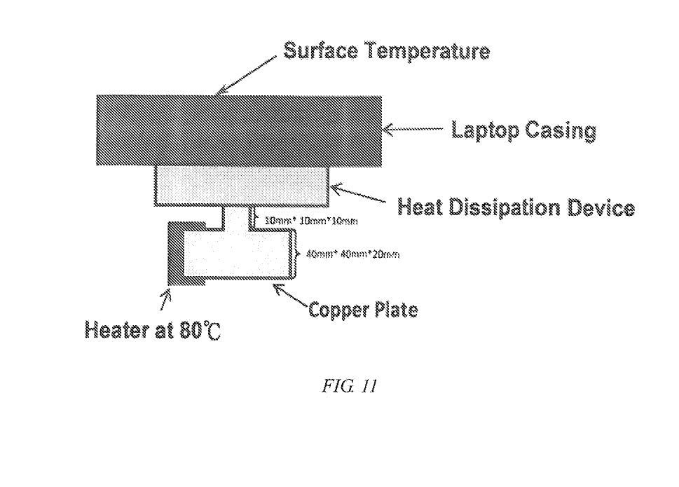

FIG. 10 illustrates another heat transfer pathway of the heat dissipation composite and a method of reducing the external surface temperature of an electronic device. In this method, the heat dissipation composite 1 is placed in direct physical contact or indirect contact with the heat source of an electronic device 100. Heat is transferred from the heat source 100 to the heat dissipating composite (pathway A), wherein a portion of the heat is reflected into the ambient air (pathway B); and the remaining heat travels through the thickness of the reflective layer 2 and then spreads across the planar direction (i.e. x-y direction) of the metal layer 3 (pathway E).

By juxtaposition of the metal layer 3 and the insulating layer 5, an anisotropic composite is formed whereby the heat can spread across the planar direction of the metal layer 3.

In some instances of executing the above methods, there can be less heat transferred to the heat dissipation composite 1 because the reflective film 2 reflects a portion of the heat away from the composite 1 (pathway B). The reflected heat is then dissipated in the ambient air through radiation. In addition, less heat reaches the external surface of the electronic device as heat is spread out through the anisotropic composite (pathways D and E). By using various cooling mechanisms, the heat dissipation composite of at least some embodiments can increase heat dissipation and reduce the external surface temperature of the electronic device as compared to more conventional approaches.

The following examples further illustrate some embodiments. These examples are intended merely to be illustrative and are not to be construed as being limiting.

### EXAMPLE 1

### Thermal Modeling Study Using the Heat Dissipation Composite

A computer laptop was modeled for this study and three types of heat dissipation devices were used: a reflective film (Toray E6ZA100, commercially available from Toray, Japan), a flexible graphite sheet electroplated with a metal layer (flexible graphite sheet+metal), and a heat dissipation composite (reflective film+metal+flexible graphite sheet). FIG. 11 illustrates the placement of the heat dissipation device within the computer laptop for this study. In this study, the heat source comprised a copper plate about 10 mm(length)×10 mm(width)×10 mm(height) and 40 mm(length)×40 mm(width)×20 mm(height) in size and a heater (King I Electric Heaters Co, Ltd, Φ6.3/110V/200 W).

The heat dissipation device was about 100 mm×100 mm in size and interposed between the heat source and the laptop's plastic casing. The study was conducted at room temperature (25° C.)

The heater was pre-heated to 80° C. prior to the commencement of the study. The external surface temperature of the laptop casing was measured every 30 seconds for 10 minutes using a thermometer (Model TM-946 from Lutron, Taiwan). The temperature was measured at the “surface temperature” point in FIG. 11.

The study results are summarized in Table 1. The maximum recorded external surface temperature was 71.3° C. in the group without any heat dissipation device, 69.8° C. in the reflective film group, 67.9° C. in the graphite sheet+metal layer group, and 52.3° C. for the heat dissipation composite. Using the maximum external surface temperature in the group without any heat dissipation device as a reference, the reflective film reduced the external surface temperature by 1.5° C., the graphite sheet+metal layer reduced the external surface temperature by 3.4° C. and the heat dissipation device according to this embodiment reduced the external surface temperature by 19.0° C.

The results show that the heat dissipation composite according to this embodiment is more efficient in dissipating heat in an electronic device compare to a reflective film or a graphite sheet alone.

TABLE 1
The External Surface Temperature of the Electronic
Device using 3 different heat dissipation devices.

| | Temperature in C. ° | | | |
|---|---|---|---|---|
| | No Heat | | | Reflective |
| | Dissipation | Reflective | Graphite | Film + Graphite |
| | Device | Film | Sheet + Metal | Sheet + Metal |
| | Thickness: | Thickness: | Thickness: | Thickness: |
| Time | 0 mm | 0.12 mm | 0.071 mm | 0.176 mm |
| 0 sec | 30 | 30 | 30 | 30 |
| 30 sec | 50.0 | 53.7 | 51.5 | 41.5 |
| 60 sec | 65.1 | 62.4 | 54.2 | 45.8 |
| 90 sec | 67.6 | 65.6 | 57.2 | 49.8 |
| 120 sec | 69.0 | 67.2 | 59.2 | 50.4 |
| 150 sec | 70.1 | 67.9 | 61.1 | 50.7 |
| 180 sec | 71.0 | 68.4 | 63.5 | 51.0 |
| 210 sec | 70.9 | 68.8 | 64.3 | 51.2 |
| 240 sec | 71.1 | 68.8 | 65.1 | 51.3 |
| 270 sec | 71.2 | 68.9 | 65.5 | 51.5 |
| 300 sec | 71.3 | 68.9 | 65.8 | 51.6 |
| 330 sec | 71.3 | 69.1 | 66.1 | 51.8 |
| 360 sec | 71.0 | 69.1 | 66.5 | 51.8 |
| 390 sec | 70.9 | 69.3 | 66.8 | 51.9 |
| 420 sec | 70.9 | 69.5 | 67.1 | 52.1 |
| 450 sec | 70.5 | 69.4 | 67.2 | 52.0 |
| 480 sec | 70.7 | 69.5 | 67.3 | 51.9 |
| 510 sec | 70.8 | 69.8 | 67.5 | 52.3 |
| 540 sec | 71.2 | 69.6 | 67.5 | 52.2 |
| 570 sec | 70.8 | 69.2 | 67.9 | 52.2 |
| 600 sec | 71.1 | 69.1 | 67.7 | 52.3 |

1. A device comprising:
a heat dissipation composite, comprising:
a reflective film configured to reflect heat energy; and
an anisotropic component, wherein the reflective film forms an outer major surface boundary of the composite.

2. The device of claim 1, wherein the anisotropic component is a graphite sheet.

3. The device of claim 2, further comprising a metal layer, wherein the metal layer is interposed between the reflective film and the graphite sheet.

4. The device of claim 3, wherein the metal layer is electroplated on to the graphite sheet.

5. The device of claim 1, wherein the reflective film is in direct physical contact with the anisotropic component or another sheet of the heat dissipation composite, wherein the reflective film does not cover any of the edges of the anisotropic component or the sheet that it contacts.

6. The device of claim 1, wherein the reflective film has a reflectivity of at least 70%.

7. The device of claim 1, further comprising one or more adhesives.

8. The device of claim 1, wherein the anisotropic component comprises a metal layer and an insulating film, wherein the metal layer is interposed between the reflective film and the insulating film.

9. The device of claim 9, wherein the anisotropic component is devoid of graphite.

10. The heat dissipation composite of claim 9, further comprising a graphite sheet.

11. A device, comprising:
a heat dissipation composite, comprising:
a reflective film configured to reflect thermal energy;
a metal layer; and
a graphite sheet,
wherein the metal layer is interposed between the reflective film and the graphite sheet.

12. The device of claim 11, further comprising one or more adhesives.

13. The device of claim 11, wherein the reflective film forms an outer major surface boundary of the composite.

14. The device of claim 11, wherein the metal layer is electroplated to the graphite sheet.

15. A device, comprising:
a means for managing heat energy, comprising:
means for reflecting heat energy; and
means for dissipating heat having an anisotropic property.

16. The device of claim 15, wherein the means for dissipating heat having an anisotropic property is a graphite sheet.

17. The device of claim 15, wherein the means for dissipating heat having the anisotropic property is formed by juxtaposition of a metal layer and an insulating layer.

18. The device of claim 15, wherein the means for reflecting heat is a reflective film.

19. The device of claim 18, wherein the reflective film has a reflectivity of at least 70%.

20. A method, comprising:
reducing an external surface temperature of an electronic device, which comprises the following actions:
(a) placing a heat dissipation composite in heat transfer communication with the heat source;
(b) transferring heat from the heat source to the heat dissipating composite,
(c) reflecting a portion of the heat transferred from the heat source into the ambient air without passing through the heat dissipation composite; and
(d) dissipating a portion of the heat transferred from the heat source through the planar direction of the heat dissipation composite.

21. The method of claim 20, wherein:
the action of reflecting a portion of the heat transferred from the heat source into the ambient air is executed using a reflective film having a reflectivity of at least 70%.

22. The method of claim 20, wherein:
the heat dissipation composite comprises:
a reflective film configured to reflect heat energy; and
an anisotropic component, wherein
the reflective film forms an outer major surface boundary of the composite.

23. The method of claim 22, wherein the anisotropic component is a graphite sheet.

24. The method of claim 23, further comprising a metal layer, wherein the metal layer is interposed between the reflective film and the graphite sheet.

25. The method of claim 22, wherein the anisotropic component comprises a metal layer and an insulating film, wherein the metal layer is interposed between the reflective film and the insulating film.
